(19) United States
(12) Patent Application Publication
(10) Pub. No.: US 2024/0222207 A1
(43) Pub. Date: Jul. 4, 2024

(54) PACKAGE SUBSTRATE HAVING DEPRESSION

(71) Applicant: TEXAS INSTRUMENTS INCORPORATED, Dallas, TX (US)

(72) Inventors: Michael LUEDERS, Freising (DE); Giacomo CALABRESE, Freising (DE); Jonathan Almeria NOQUIL, Plano, TX (US)

(21) Appl. No.: 18/091,349

(22) Filed: Dec. 29, 2022

(51) Int. Cl. H01L 23/13; G02B 6/12; H01F 27/26; H01F 27/28; H01L 21/48; H01L 23/498; H01L 25/16

(52) U.S. Cl. CPC H01L 23/13; G02B 6/12004; H01F 27/266; H01F 27/2804; H01L 21/4857; H01L 23/49822; H01L 23/49838; H01L 25/16; H01L 28/10; H01F 2027/2809; H01L 23/49894

(57) ABSTRACT

In examples, a packaged integrated circuit (IC) comprises a package substrate having opposite first and second surfaces and including metal interconnects surrounded by an insulation material. The package substrate includes a depression region that extends from the first surface, and the depression region includes a material different from the insulation material and the metal interconnects. The packaged IC also comprises a semiconductor die on part of the first surface adjacent to the depression region. The semiconductor die includes circuitry coupled to the metal interconnects. The packaged IC also comprises a mold compound covering the semiconductor die and the depression region.

### BACKGROUND

A packaged integrated circuit (IC) includes a semiconductor die having circuitry that is configured to perform one or more operations. The packaged IC also includes a package substrate, such as a lead frame die pad, to which the semiconductor die is coupled. The semiconductor die and the package substrate may be covered by a mold compound. Conductive terminals, such as leads or pins, are coupled to the semiconductor die and may be exposed to an external surface of the mold compound. In some applications, the packaged substrate includes multiple layers of metal interconnects (e.g., a network of metal interconnects coupled by vias) covered by an insulation material, such as a build-up film.

### SUMMARY

In examples, a packaged integrated circuit (IC) comprises a package substrate having opposite first and second surfaces and including metal interconnects surrounded by an insulation material. The package substrate includes a depression region that extends from the first surface, and the depression region includes a material different from the insulation material and the metal interconnects. The packaged IC also comprises a semiconductor die on part of the first surface adjacent to the depression region. The semiconductor die includes circuitry coupled to the metal interconnects. The packaged IC also comprises a mold compound covering the semiconductor die and the depression region.

In examples a method comprises forming a first substrate layer, in which the first substrate layer has opposite first and second surfaces and includes a metal layer extending between the first and second surfaces and an insulation material abutting the metal layer. The method also comprises forming a first resist layer on the first surface covering the metal layer and forming a second substrate layer on the first resist layer, the second substrate layer including the insulation material. The method also comprises forming a second resist layer on the second surface covering part of the first substrate layer abutting the metal layer and etching away the metal layer to form a depression region including the first resist layer. The method also includes removing the second resist layer.

### BRIEF DESCRIPTION OF THE DRAWINGS

FIG. 1 is a schematic illustrating a cross-sectional view of an example packaged integrated circuit (IC).

FIG. 2 is a graph depicting a relationship between a thickness of the package substrate and a strength of an electric field that propagates out of the package substrate.

FIG. 3 is a schematic illustrating a cross-sectional view of a package substrate having multiple depressions, in accordance with various examples.

FIGS. 4A and 4B are schematics illustrating top and cross-sectional views, respectively, of a packaged IC having multiple depressions containing magnetic mold compound, in accordance with various examples.

FIGS. 5A and 5B are schematics illustrating top and cross-sectional views, respectively, of a packaged IC having a depression containing an optoisolator, in accordance with various examples.

FIG. 6 is a schematic illustrating a cross-sectional view of a package substrate having multiple depressions, in accordance with various examples.

FIG. 7 is a schematic illustrating a cross-sectional view of a packaged IC having multiple depressions, in accordance with various examples.

FIG. 8 is a schematic flow diagram illustrating an example method of manufacturing a package substrate having a depression, in accordance with various examples.

FIGS. 9A-9E are process flow schematics illustrating an example method of manufacturing a package substrate having multiple depressions, in accordance with various examples.

FIGS. 10A-10E are process flow schematics illustrating an example method of manufacturing a package substrate having multiple depressions, in accordance with various examples.

FIGS. 11A-11F are process flow schematics illustrating an example additive method of manufacturing a package substrate having multiple depressions, in accordance with various examples.

FIGS. 12A-12D are process flow schematics illustrating an example subtractive method of manufacturing a package substrate having multiple depressions, in accordance with various examples.

### DETAILED DESCRIPTION

As described above, some package substrates include multiple layers of metal interconnects (e.g., a network of metal interconnects coupled by vias) surrounded by an insulation material, such as a build-up film (e.g., AJINOMOTO® build-up film (ABF)), and mold compound. In some applications, it may be beneficial to increase the thickness of a package substrate, because a thicker substrate may reduce electric field excursions outside of the packaged IC. In this way, electric fields generated by metal interconnects within the substrate have reduced impact on structures outside of the substrate. Further, in some applications (e.g., high current applications), thick substrates may be useful for accommodating thick metal interconnects within the substrate. Also, in some applications, it may be beneficial to have a package substrate having depressions/cavities to accommodate various circuit components, which can reduce the overall footprint and height of the packaged IC.

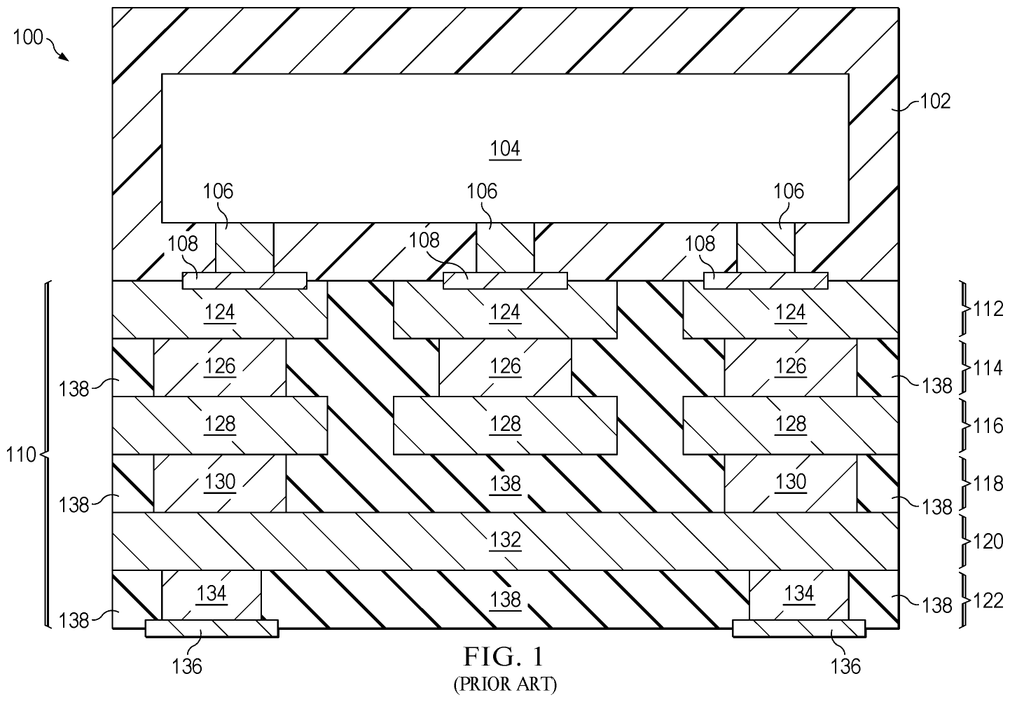

FIG. 1 is a schematic illustrating a cross-sectional view of an example packaged IC 100. The packaged IC 100 includes a mold compound 102 that covers a semiconductor die 104. The semiconductor die 104 is coupled to a package substrate 110 by way of metal pillars 106 and metal pads (e.g., solder joints) 108. The package substrate 110 includes multiple substrate layers 112, 114, 116, 118, 120, and 122. The substrate layers 112, 116, and 120 include metal interconnects 124, 128, and 132 (e.g., metal traces). The substrate layers 114, 118, and 122 include metal interconnects 126, 130, and 134 (e.g., vias). The metal interconnects 134 are coupled to metal pads (e.g., solder joints) 136. An insulation material 138 (e.g., ABF) surrounds and/or abuts the various structures of the package substrate 110. The thicknesses of the metal interconnects 124, 126, 128, 130, 132, and 134 (e.g., metal traces, vias) may be approximately 200 microns. These metal interconnects can be further thickened to carry higher levels of current with reduced resistance, and the package substrate 110 can be thickened to accommodate the thickened metal interconnects.

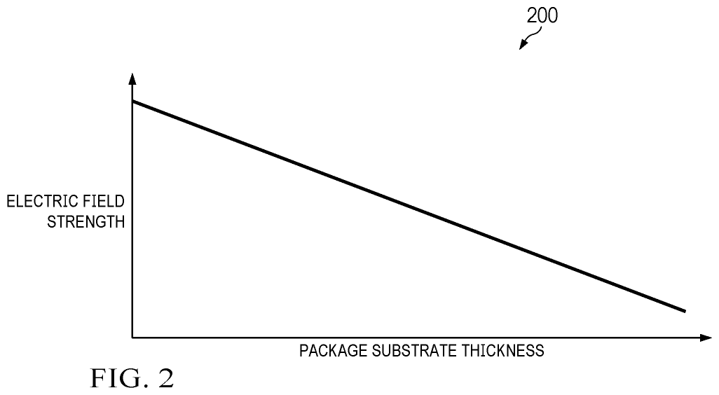

In some examples, the thickness of the package substrate 110 can be further increased to prevent electric fields generated by the metal interconnects (e.g., 124, 126, 128, 130, 132, and 134) from propagating out of packaged IC 100, which may affect other electronic components external to packaged IC 100 or create safety issues (e.g., arcing). FIG. 2 is a graph 200 depicting a relationship between a thickness of the package substrate 110 and the strength of an electric field that propagates/leaks out of package substrate 110. As shown in graph 200, as the thickness of the package substrate 110 increases, the leaked electric field strength decreases. Accordingly, to reduce the strength of electric field that propagates out of package substrate 110, it is advantageous to increase the thickness of the package substrate 110.

Although increasing the thickness of the package substrate 110 can accommodate thicker metal interconnects and reduce the leakage of the electric field out of the package substrate 110, uniformly increasing the thickness of the package substrate 110 may present challenges. Specifically, a packaged IC may include other circuit components, such as inductors, capacitors, etc., and if those components are placed on a thick package substrate, it may increase the overall height of the packaged IC, even if the metal interconnects underneath those circuit components do not generate strong electric fields and do not need a thickness package substrate to attenuate the leaked electric fields. Also, various tools for handling the package substrate may have a limit on the thickness of the package substrate. Increasing the thickness of the package substrate beyond the limit may present challenges for the tools.

This disclosure describes apparatus and methods that can address at least some of the challenges described above. More specifically, this disclosure describes examples of a method for manufacturing a packaged IC that includes the formation of a relatively thick package substrate (e.g., 400 microns) having cavities. The thick portion of the package substrate can accommodate thickened metal interconnects, and can also reduce the strength of electric fields that propagate/leak out of the package substrate. Also, the cavities can contain various components of the packaged IC, such as inductors, magnetic mold compound to concentrate the magnetic flux of the inductors, optical coupler, etc. By placing these components in the cavities instead of on the thick portion of the package substrate, the overall height of the packaged IC can be reduced, which allow the packaged IC to be more compact.

In some examples, the package substrate can include depressions (or indents) on opposing ends of the package substrate, where the thickness at the depressions is less than the thickness of the middle portion of the package substrate. Such depressions can serve various purposes. For example, the packaged IC can include additional circuit components in the depressions. The depression can also facilitate handling of the package substrate by the tools.

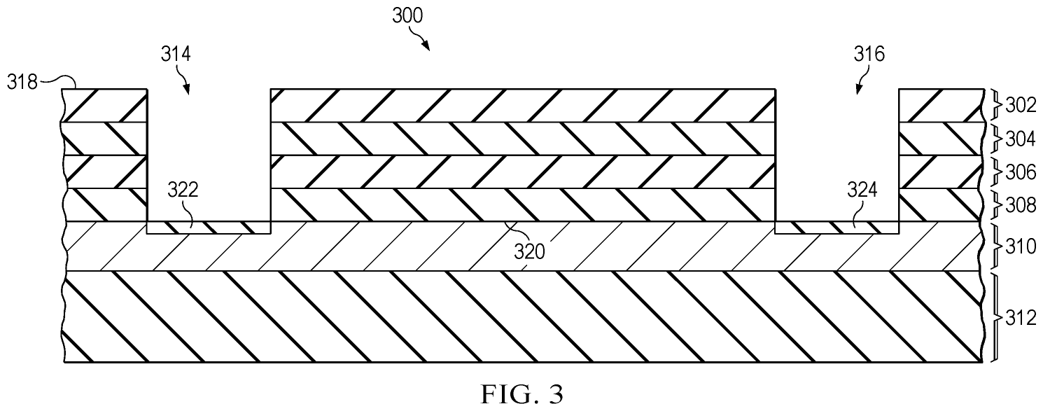

FIG. 3 is a schematic illustrating a cross-sectional view of a substrate 300 having multiple depressions, in accordance with various examples. The substrate 300 can be a package substrate and can include a number of substrate layers forming a stack. FIG. 3 shows six example substrate layers 302, 304, 306, 308, 310, and 312. Each of these substrate layers includes metal interconnects (not expressly shown). For example, the substrate layers 302, 306 and 310 may include metal traces, and the substrate layers 304, 308 and 312 may include vias connecting the metal traces to each other. In this way, the substrate layers of the package substrate 300 form a network of metal interconnects. In addition to the metal interconnects, each of the substrate layers may include an insulation material, such as a build-up film (e.g., AJINOMOTO® build-up film (ABF)), a mold compound, etc. The insulation material surrounds and/or abuts the various metal interconnects of the substrate layers.

The substrate 300 may include depressions/cavities 314 and 316. The depressions 314 and 316 are useful to contain various structures (e.g., optoisolators, magnetic mold compounds), as described above. The depressions that thin the substrate so that manufacturing equipment is able to handle the substrate are described further below. Each of the depressions 314 and 316 is a cavity that extends from a top surface 318 of the package substrate 300 and into the package substrate 300. For example, the depressions 314 and 316 extend from the top surface 318 to an interface 320 between the substrate layers 308 and 310. In other examples, depressions may have different depths and may terminate at different locations within the package substrate 300. The distal end of depression 314 (e.g., the farthest point in the depression 314 from the top surface 318) includes an etch resist layer (also referred to herein as a resist layer) 322. Similarly, the distal end of the depression 316 includes a resist layer 324. The resist layers 322 and 324 may include various materials. In some examples, the resist layers 322 and 324 may include the same insulation material included in the package substrate 300 (e.g., build-up film, mold compound, etc.). In some examples, the resist layers 322 and 324 may include a material different from the insulation material, such as polyimide, platinum, or solder mask.

The depressions 314 and 316 may contain various components. For example, the depressions 314 and 316 may contain a magnetic mold compound, as described below. The depressions 314 and 316 may contain passive components, such as capacitors, inductors, etc., and in such examples, the resist layers 322 and 324 may be removed to enable metal interconnects in the substrate layer 310 to couple to contact pads of such passive components. In some examples, the depressions 314 and 316 have similar or identical contents, and in other examples, the depressions 314 and 316 have different contents. The scope of this disclosure is not limited to any particular number of depressions. For example, the package substrate 300 may include a single depression, and such a depression may contain, e.g., an optoisolator, as described below. In some examples, the depressions 314 and/or 316 may include metal, and in some such examples, the metal in the depressions 314 and/or 316 is different than a metal used for the metal interconnects in the various substrate layers 302, 304, 306, 308, 310, and/or 312. For example, in a case where the metal interconnects in the various substrate layers 302, 304, 306, 308, 310, and/or 312 are copper, the metal in the depressions 314 and/or 316 may include silver to provide a higher conductivity/lower resistance than copper, and may be deposited by plating, sputtering, or any other suitable technique.

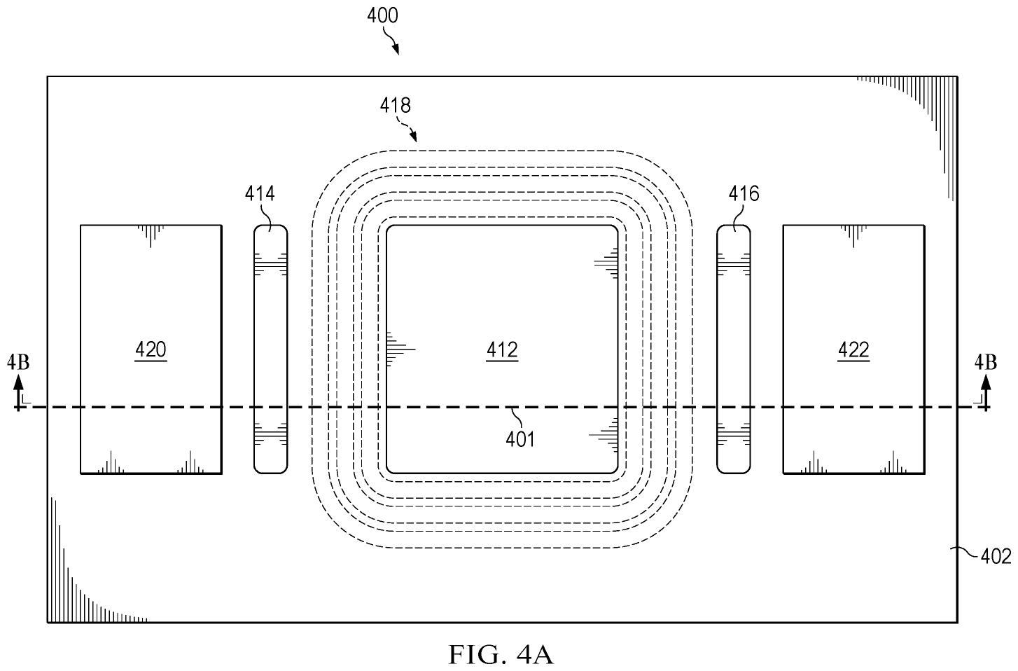

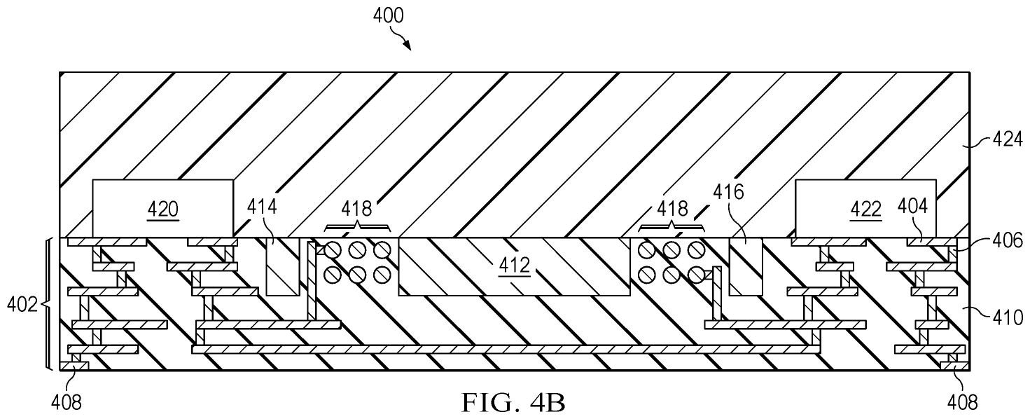

FIGS. 4A and 4B are schematics illustrating top and cross-sectional views, respectively, of a packaged IC having multiple depressions containing magnetic mold compound, in accordance with various examples. The packaged IC 400 is an example implementation of the substrate 300 described above with reference to FIG. 3. FIG. 4A is a top view of the packaged IC 400, and FIG. 4B is a cross-sectional view of the packaged IC 400 along a cross-section line 401. The packaged IC 400 includes a substrate 402. The substrate 402 includes metal interconnects 404, such as metal traces, extending in a horizontal direction (e.g., approximately in parallel with the length of the substrate 402). The substrate 402 includes metal interconnects 406, such as metal vias, extending in a vertical direction (e.g., approximately orthogonal with the length of the substrate 402). Each of the metal interconnects 404 and 406 may belong to a different substrate layer in the substrate 402, similar to the substrate layers that were described above with reference to FIG. 3. The substrate 402 includes contact pads 408, such as pins, that can couple to another electronic component, such as a printed circuit board (PCB). An insulation material 410, such as ABF, surrounds and/or abuts the metal interconnects 404 and 406 and the contact pads 408. The substrate 402 further includes magnetic mold compounds 412, 414 and 416 (e.g., metal particles suspended in resin). Each of the magnetic mold compounds 412, 414 and 416 may be contained in a separate depression, such as the depressions 314 and 316 that were described above with reference to FIG. 3. The substrate 402 may include one or more metal coils 418 that are wound around the magnetic mold compound 412, that extend between the magnetic mold compounds 412 and 414, and that extend between the magnetic mold compounds 412 and 416. The one or more metal coils 418 may couple to one or more of the metal interconnects 404, 406, as shown.

The packaged IC 400 includes semiconductor dies 420 and 422. The semiconductor dies 420 and 422 may be coupled to the metal interconnects 404, as shown. In examples, the semiconductor dies 420 and 422 may be coupled to the metal interconnects 404 using solder bumps, solder paste, copper pillars, a combination thereof or other coupling structures (not expressly shown). Thus, in this example, the semiconductor dies 420 and 422 couple to each other and to the one or more metal coils 418 by way of the metal interconnects 404 and 406. A mold compound 424 covers the semiconductor dies 420 and 422 and the substrate 402. For instance, the mold compound 424 may directly contact the magnetic mold compounds 412, 414 and 416. By providing depressions that are filled by the magnetic mold compounds 412, 414 and 416, the magnetic mold compounds 412, 414, and 416 can be more tightly coupled to metal coils 418, which increases the degree by which the magnetic mold compounds concentrates the magnetic flux density and improves the efficiency of the metal coils in converting between electrical and magnetic energies. Also, the magnetic mold compounds does not add to the height of the packaged IC 400, which allows the packaged IC 400 to be more compact.

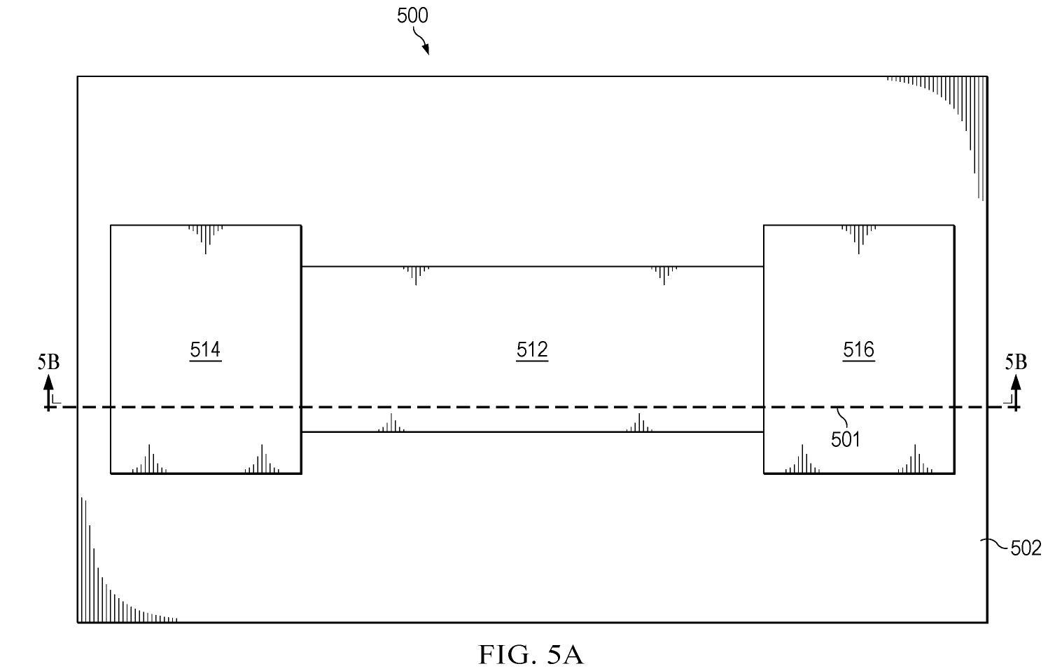

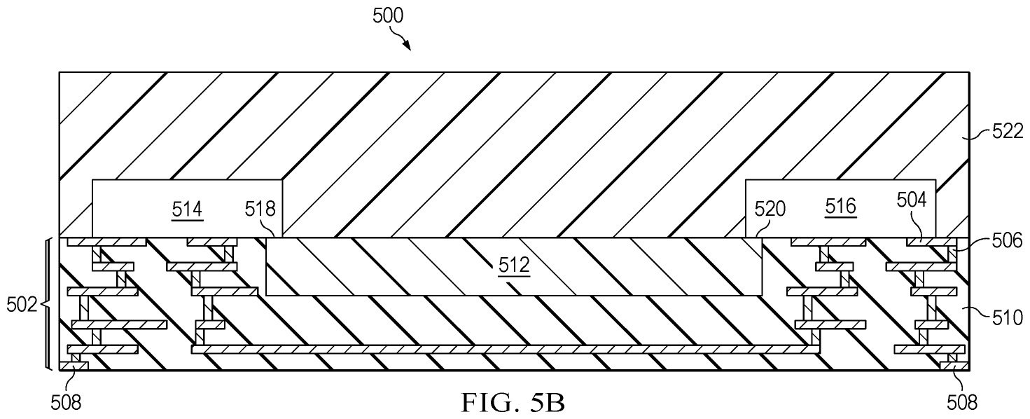

FIGS. 5A and 5B are schematics illustrating top and cross-sectional views, respectively, of a packaged IC having a depression containing an optoisolator, in accordance with various examples. The packaged IC 500 is an example implementation of the package substrate 300 described above with reference to FIG. 3. FIG. 5A is a top view of the packaged IC 500, and FIG. 5B is a cross-sectional view of the packaged IC 500 along a cross-section line 501. The packaged IC 500 includes a substrate 502. The substrate 502 includes metal interconnects 504, such as metal traces, extending in a horizontal direction (e.g., approximately in parallel with the length of the substrate 502). The substrate 502 includes metal interconnects 506, such as metal vias, extending in a vertical direction (e.g., approximately orthogonal with the length of the substrate 502). Each of the metal interconnects 504 and 506 may belong to a different substrate layer in the substrate 502, similar to the substrate layers that were described above with reference to FIG. 3. The substrate 502 includes contact pads 508, such as pins, that can couple to another electronic component, such as a printed circuit board (PCB). An insulation material 510, such as ABF, surrounds and/or abuts the metal interconnects 504 and 506 and the contact pads 508. The substrate 502 further includes an optoisolator 512, such as a transparent epoxy polymer. The optoisolator 512 may be contained in a depression, such as one of the depressions 314 and 316 that were described above with reference to FIG. 3. The packaged IC 500 may include semiconductor dies 514 and 516 that are coupled to metal interconnects 504, as shown. In examples, the semiconductor dies 514 and 516 may be coupled to the metal interconnects 504 using solder bumps, solder paste, copper pillars, a combination thereof or other coupling structures (not expressly shown). Thus, in this example, the semiconductor dies 514 and 516 couple to each other by way of the metal interconnects 504 and 506. The semiconductor dies 514 and 516 both abut the optoisolator 512 and are configured to provide optical signals to and receive optical signals from the optoisolator 512 by way of interfaces 518 and 520, respectively. A mold compound 522 covers the semiconductor dies 514 and 516, the optoisolator 512, and portions of the substrate 502. The arrangements in FIG. 5 can reduce the separation between the optoisolator 512 and the semiconductor dies 514 and 516, which can facilitate the transmission of signal between the semiconductor dies 514 and 516 via the optoisolator 512 (e.g., by reducing noise and optical power). Also, by putting the optoisolator 512 in the depressions rather than on the thick portion of the substrate 502, the optoisolator 512 does not add to the height of the packaged IC 500, which allows the packaged IC 500 to be more compact.

FIG. 6 is a schematic illustrating a cross-sectional view of a substrate 600 having multiple depressions, in accordance with various examples. The substrate 600 can be a package substrate and includes multiple substrate layers 602, 604, 606, 608, 610, and 612. Each of these substrate layers includes metal interconnects. For example, the substrate layers 602, 606, and 610 may include metal traces, and the substrate layers 604, 608, and 612 may include vias connecting the metal traces to each other. In this way, the substrate layers of the substrate 600 form a network of metal interconnects. In addition to the metal interconnects, each of the substrate layers may include an insulation material (e.g., a build-up film or a mold compound). The insulation material surrounds and/or abuts the various metal interconnects of the substrate layers.

The substrate 600 may include depressions 614 and 616, which can be in the form of indents. Each of the depressions 614 and 616 extends from a top surface 618 of the substrate 600 and into the substrate 600. For example, the depressions 614 and 616 extend from the top surface 618 to an interface 620 between the substrate layers 608 and 610. In other examples, depressions may have different depths and may terminate at different locations within the substrate 600. The distal end of depression 614 (e.g., the farthest point in the depression 614 from the top surface 618) includes a resist layer 622. Similarly, the distal end of the depression 616 includes a resist layer 624. The resist layers 622 and 624 may include the same insulation material of the substrate 600, or other materials such as polyimide, platinum, or solder mask.

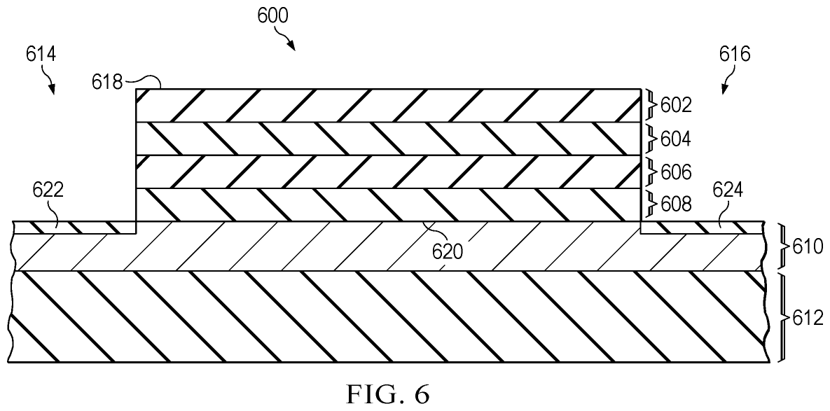

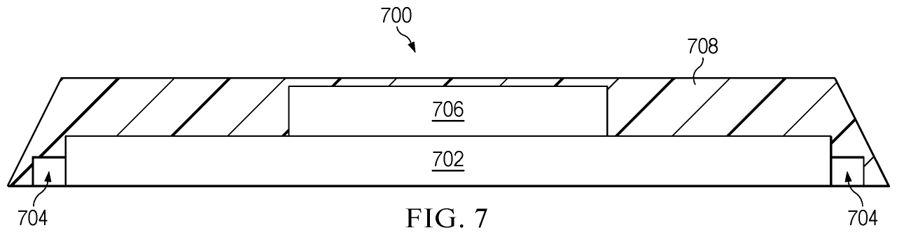

FIG. 7 is a schematic illustrating a cross-sectional view of a packaged IC 700 having multiple lateral depressions, in accordance with various examples. The packaged IC 700 includes a substrate 702, which can be substrate 600 of FIG. 6, a semiconductor die 706 mounted on the substrate 702, and a mold compound 708 that covers the semiconductor die 706 and the substrate 702. The substrate 702 includes thin portions 704, which forms depressions/indents 614 of FIG. 6. The depressions/indents may contain various components, such as passive components (e.g., inductors, capacitors, etc.), magnetic mold compounds (as in FIGS. 4A and 4B), etc. In some examples, the depressions may also include the mold compound 708.

In some examples, the package substrate is manufactured in a build-up process, combining copper plating and film molding. It can be processed top-down, i.e., with the top trace layer as the bottom layer. A dry film can be applied and patterned, and the copper is platted where the dry film is removed. After this, the dry film can be removed completely, and the insulation material (e.g., ABF) can be molded. After planarizing the surface, the subsequent layer can be applied (build up process). Some of the plated copper can then be selectively removed, and the insulation material can act as both vertical/horizontal etch stop. In addition, some other materials, such as platinum, can provide the vertical etch stop.

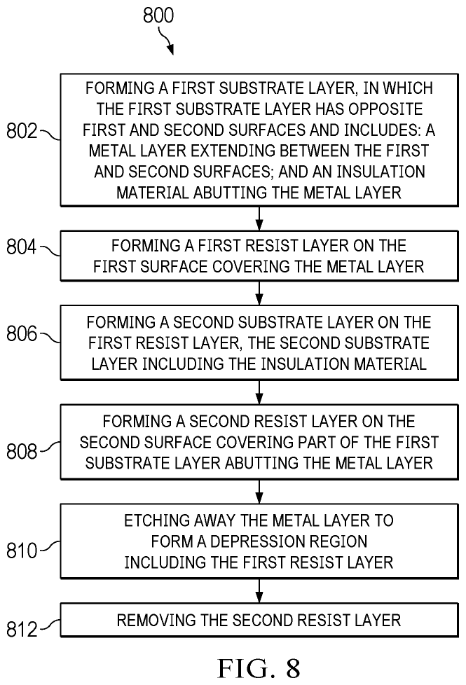

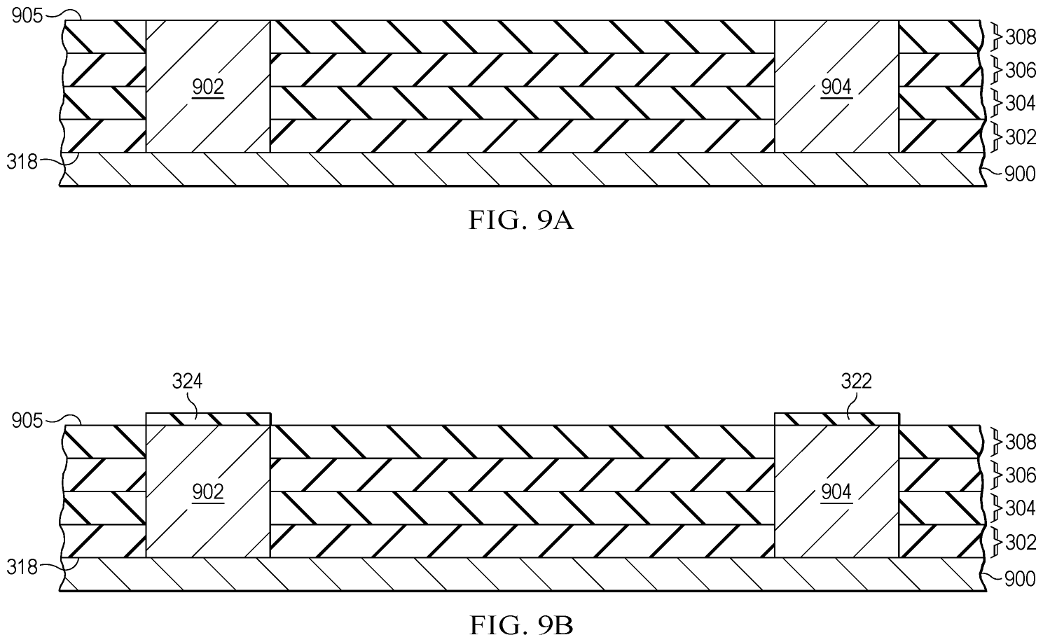

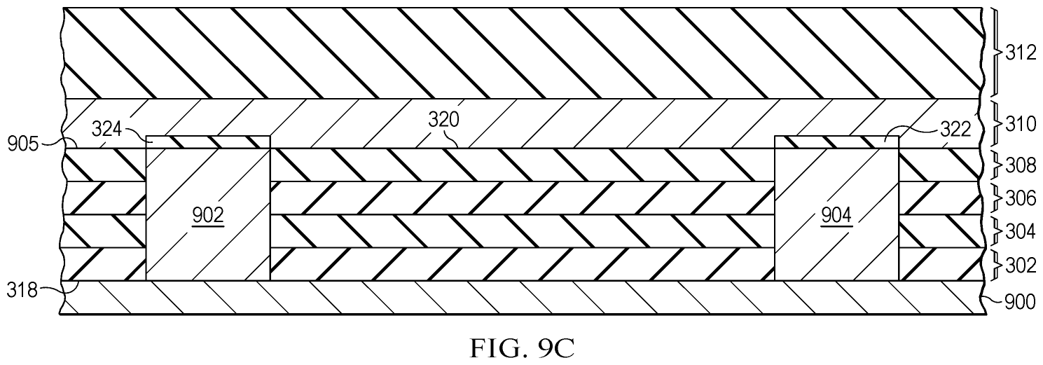

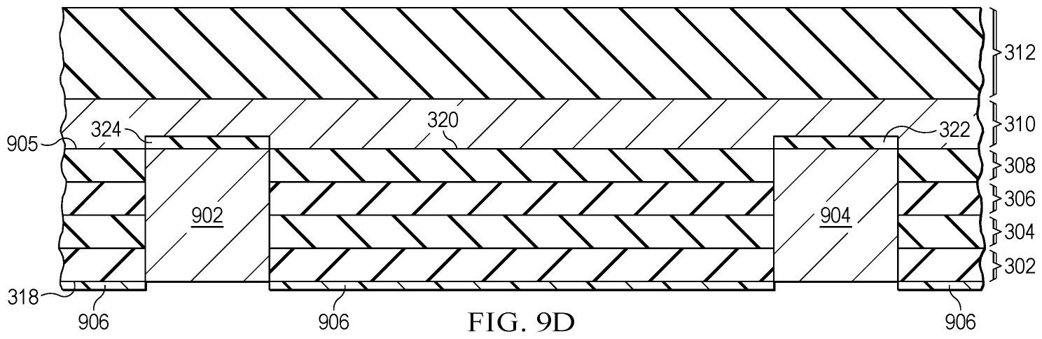

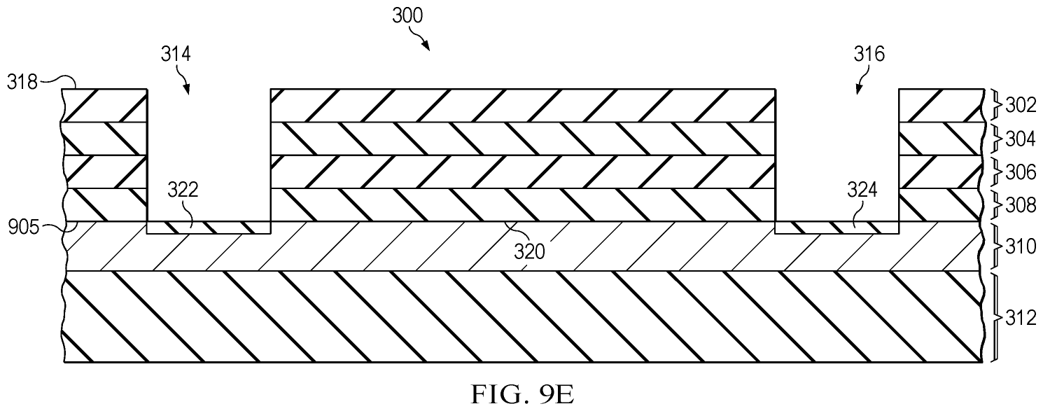

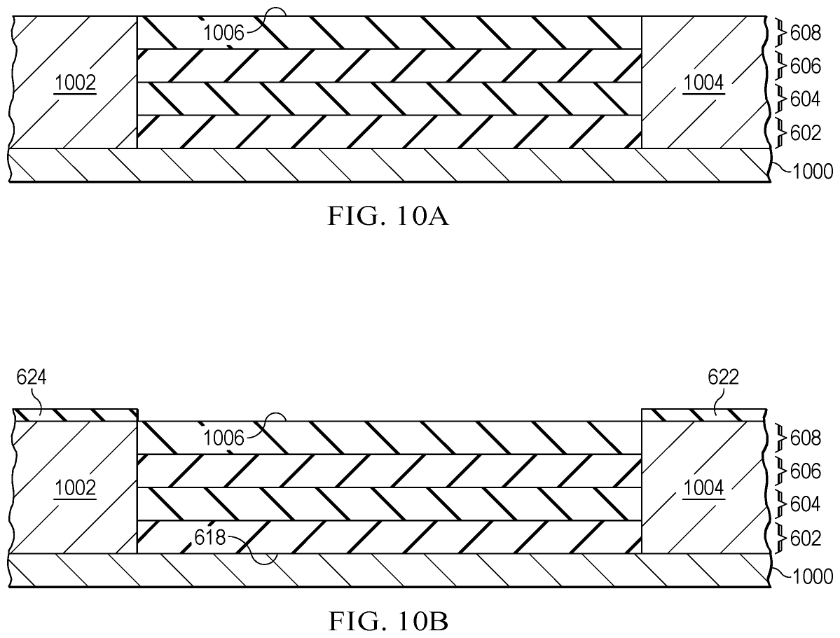

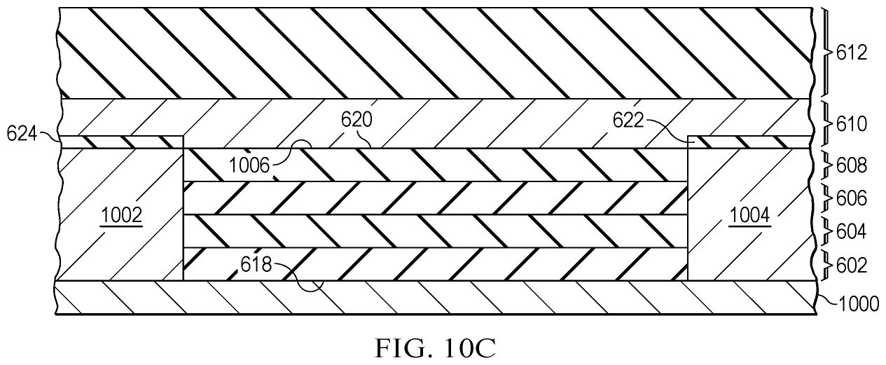

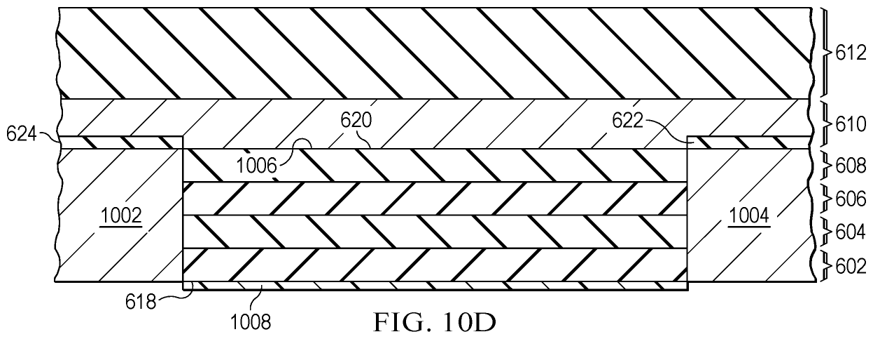

FIG. 8 is a schematic flow diagram illustrating a method 800 for manufacturing a package substrate having a depression, in accordance with various examples. FIGS. 9A-9E and 10A-10E are schematic process flows for manufacturing package substrates having multiple depressions, in accordance with various examples. More particularly, the process flow of FIGS. 9A-9E depicts the formation of the substrate 300 of FIG. 3 having cavity-type depressions 314 and 316. The process flow of FIGS. 10A-10E depicts the formation of the substrate 600 of FIG. 6 having lateral depressions 614 and 616 on opposing ends. Although the formation of these two types of depressions are depicted in separate process flows, in some examples, a substrate may be manufactured having both types of depressions. The process flows of FIGS. 9A-9E and 10A-10E are now described in parallel with the method 800 of FIG. 8.

In step 802, a first substrate layer having opposing first and second surfaces is formed. The first substrate layer includes a metal layer extending between the first and second surfaces and an insulation material abutting the metal layer. FIG. 9A illustrates the formation of multiple substrate layers 302, 304, 306, and 308 (FIG. 3) on any suitable type of carrier 900. The “first substrate layer” of step 802 may refer to the combination of the example substrate layers 302, 304, 306, and 308. As described above, such substrate layers may include metal interconnects (e.g., the substrate layers 302 and 306 may include metal traces, while the substrate layers 304 and 308 may include metal vias). The various metal interconnects of the substrate layers 302, 304, 306, and 308 may form a network of metal interconnects. The substrate layers may be formed in a serial manner. For example, when forming the substrate layer 302, a plating technique may be useful to form metal traces, and an insulation material may be deposited to surround the metal traces. After substrate layer 302 is formed, the substrate layer 304 may be formed by using a plating technique to form vias, and an insulation material may be deposited to surround the vias. Such a process may be repeated until the substrate layers 302, 304, 306 and 308 have been formed. During the formation of the substrate layers 302, 304, 306 and 308, metal layers may be formed in predetermined areas that are in vertical alignment, and independent of the metal traces and vias, to form metal layers 902 and 904. In examples, the metal layers 902 and 904 extend from the surface 318 (and the carrier 900) to a top surface 905 of the substrate layer 308. The insulation material of the substrate layers 302, 304, 306, and 308 may abut/surround the metal layers 902 and 904.

FIG. 10A illustrates the formation of substrate layers 602, 604, 606 and 608 (FIG. 6) on a carrier 1000. The substrate layers 602 and 606 may include insulation material and metal interconnects such as metal traces, and the substrate layers 604 and 608 may include insulation material and metal interconnects such as metal vias. Each of the substrate layers may include metal layers formed in predetermined areas that are in vertical alignment, and independent of the metal traces and vias, to form metal layers 1002 and 1004. The metal layers 1002 and 1004 extend from the carrier 1000 to a top surface 1006 of the substrate layer 608. The insulation material of the substrate layers 602, 604, 606 and 608 may abut the metal layers 1002 and 1004.

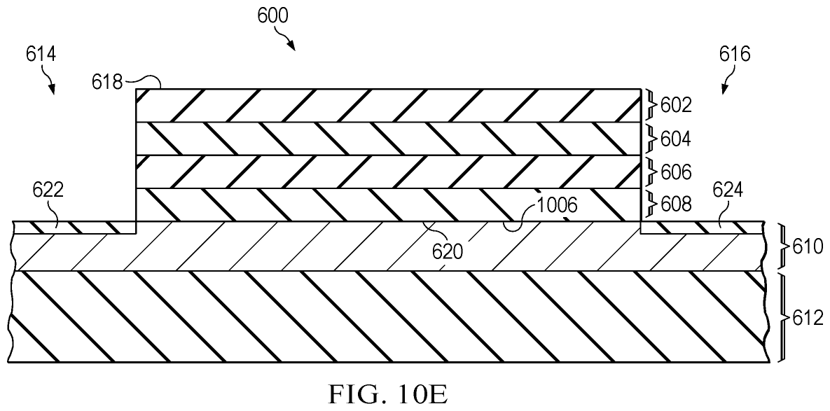

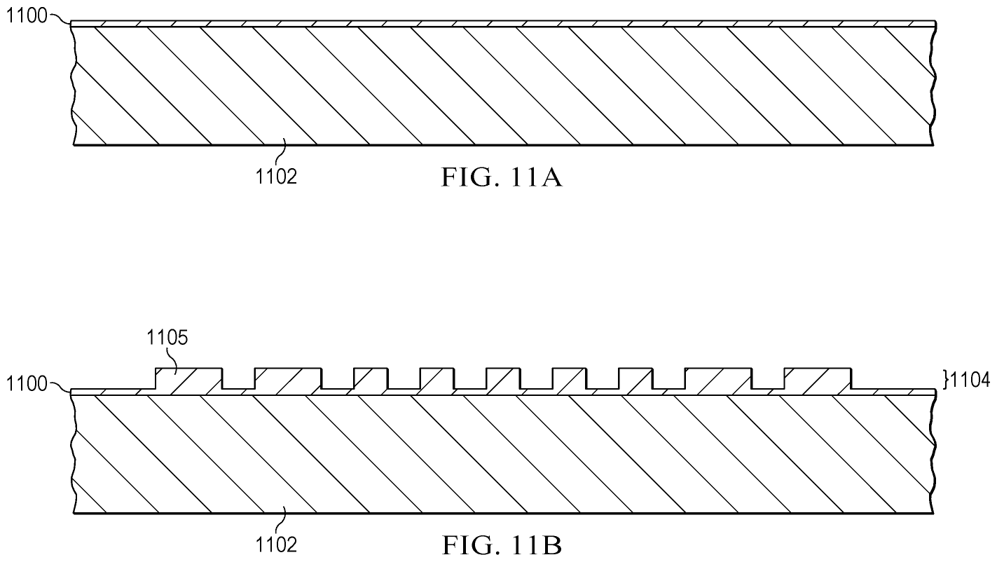

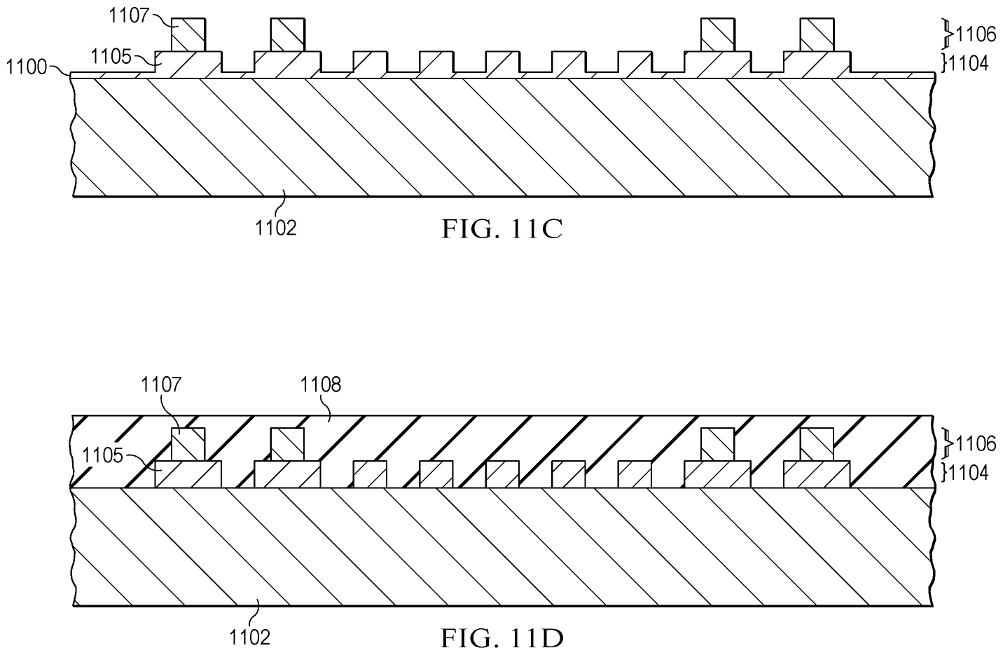

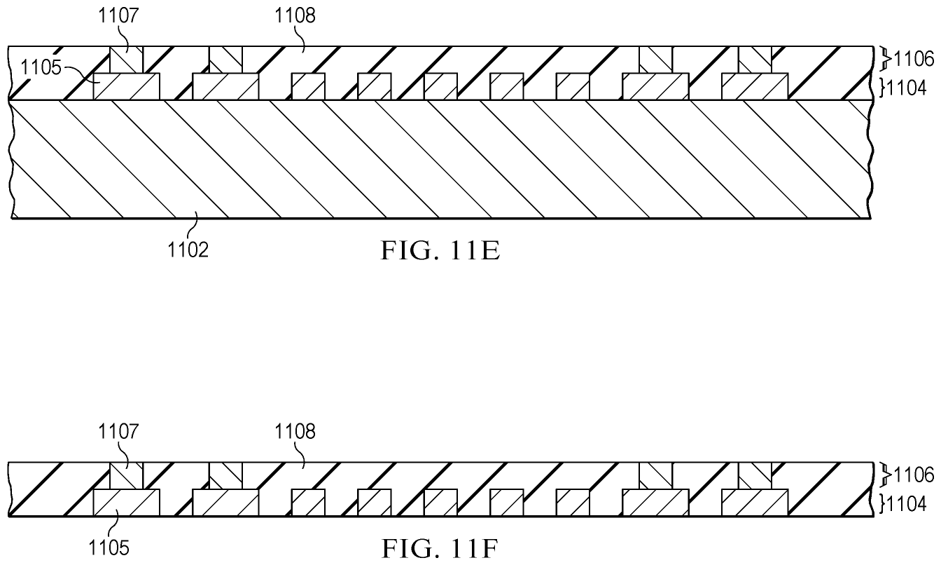

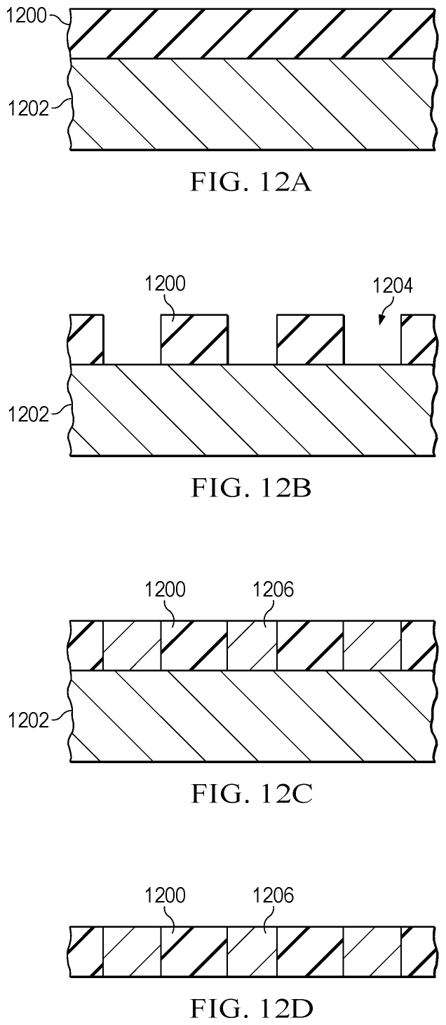

The substrate layers 302, 304, 306 and 308 and the substrate layers 602, 604, 606 and 608 may be formed using the example techniques depicted in FIGS. 11A-11F and 12A-12D. Thus, FIGS. 11A-11F and 12A-12D are now described.

FIGS. 11A-11F are schematics illustrating an example additive process flow for manufacturing package substrate layers. In FIG. 11A, a seed layer 1100 (e.g., a copper seed layer) can be deposited (e.g., by sputtering) on a metal carrier 1102. In FIG. 11B, the process flow includes forming, by a combination of plating (e.g., electroplating) and photolithography, a first substrate layer 1104 having metal traces 1105. In the cross-sectional view of FIG. 11B, the metal traces 1105 do not appear to be coupled to each other, but other views may reveal a metal trace pattern whereby the various metal traces 1105 are coupled to each other. In FIG. 11C, the process flow includes forming, by a combination of plating and photolithography, a second substrate layer 1106 having metal vias 1107. The metal vias 1107 are coupled to metal traces 1105, as shown. In FIG. 11D, the process flow includes applying an insulation material 1108 (e.g., ABF) to surround and/or abut the metal traces 1105 and metal vias 1107. In some examples, the insulation material 1108 may be applied to the metal traces 1105 prior to formation of the metal vias 1107. In some examples, portions of the seed layer 1100 may be etched away prior to application of the insulation material 1108, as shown in FIG. 11D. In FIG. 11E, the process flow includes grinding the second substrate layer 1106 to remove excess insulation material 1108 and to achieve a target thickness for the metal vias 1107. In FIG. 11F, the process flow includes removing the carrier 1102. Prior to removing the carrier 1102, the process flow steps of FIGS. 11A-11E described above may be repeated to achieve a target number of substrate layers.

FIGS. 12A-12D are schematics illustrating an example subtractive process flow for manufacturing a package substrate having multiple depressions, in accordance with various examples. Turning briefly to FIG. 12A, an insulation material 1200 can be applied/deposited on a carrier 1202. The insulation material may include a build-up film (e.g., ABF), a mold compound, etc. In FIG. 12B, the process flow may include forming cavities 1204 in the insulation material 1200. In examples, such cavities 1204 may be formed by etching/patterning the insulation material. In FIG. 12C, metal 1206 may be formed in the cavities 1204, for example, by an electroplating technique, thereby forming a complete substrate layer. Although not expressly shown, additional substrate layers may be formed. In FIG. 12D, the carrier 1202 may be removed.

Referring again to FIGS. 8, 9A-9E, and 10A-10E, the method 800 includes forming a first resist layer on the first surface covering the metal layer (804). FIG. 9B includes forming resist layers 322 and 324 on the top surface 905 and, more specifically, over the metal layers 904 and 902, respectively. As described above, the resist layers 322 and 324 may include the same insulation material as the substrate layers, such as build-up film, polyimide, platinum, etc. In a case where resist layers 322 and 324 include polyimide, they can be formed by spray coating. In a case where resist layers 322 and 324 include platinum, they can be formed by sputtering. FIG. 10B includes forming resist layers 622 and 624 on the top surface 1006, and more specifically, over the metal layers 1004 and 1002, respectively. In examples, the resist layers 622 and 624 may include the same insulation material as the substrate layers, such as build-up film, polyimide, platinum, etc. The resist layers 622 and 624 may be applied by spray coating, sputtering, etc., as described above.

Referring again to FIG. 8, in step 806, a second substrate layer is formed on the first resist layer. The second substrate layer includes the insulation material. FIG. 9C includes the formation of substrate layers 310 and 312 on the resist layers 322 and 324, as shown. The substrate layers 310 and 312 collectively constitute the “second substrate layer” of step 806. In examples, the substrate layers abutting the metal layers 902 and 904 (e.g., substrate layers 302, 304, 306 and 308) are greater in number than the substrate layers not abutting the metal layers 902 and 904 (e.g., the substrate layers 310 and 312). The substrate layer 310 may include insulation material (e.g., ABF) and metal interconnects such as metal traces. The substrate layer 312 may include insulation material (e.g., ABF) and metal interconnects such as metal vias. The substrate layers 310 and 312 may be formed using the techniques of FIGS. 11A-11F and/or 12A-12D. As shown, the substrate layer 310 abuts the resist layers 322 and 324. FIG. 10C includes the formation of substrate layers 610 and 612 on the resist layers 622 and 624, as shown. The substrate layers 610 and 612 collectively constitute the “second substrate layer” of step 806. In examples, the substrate layers abutting the metal layers 1002 and 1004 (e.g., the substrate layers 602, 604, 606 and 608) are greater in number than the substrate layers not abutting the metal layers 1002 and 1004 (e.g., the substrate layers 610 and 612). The substrate layer 610 may include insulation material (e.g., ABF) and metal interconnects such as metal traces. The substrate layer 612 may include insulation material (e.g., ABF) and metal interconnects such as metal vias. The substrate layers 610 and 612 may be formed using the techniques of FIGS. 11A-11F and/or 12A-12D. As shown, the substrate layer 610 abuts the resist layers 622 and 624.

In operation 808, a second resist layer is formed on the second surface covering part of the first substrate layer abutting the metal layer. FIG. 9D shows the application of a second resist layer 906 on the top surface 318. The properties of the second resist layer 906 may be the same as those of the first resist layers 322 and 324, and thus these properties are not described again here. FIG. 10D shows the application of a second resist layer 1008 on the top surface 618. The properties of the second resist layer 1008 may be the same as those of the first resist layers 622 and 624, and thus these properties are not described again here.

In operation 810, the metal layer is etched away to form a depression region including the first resist layer, followed by operation 812 in which the second resist layer is removed. FIG. 9E shows the etching away of the metal layers 902 and 904 and the removal of the second resist layer 906, resulting in a completed substrate 300. Similarly, FIG. 10E shows the etching away of the metal layers 1002 and 1004 and the removal of the second resist layer 1008, resulting in a completed substrate 600.

Following operation 810, the depression region can be filled with a material different from the insulation material of the package substrate, such as a magnetic molding compound, a transparent epoxy polymer, a metal (e.g., a different metal from the metal interconnects), etc. Passive circuit components, such as inductor and capacitor, can also be formed in the depression region.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

In this description, unless otherwise stated, “about,” “approximately” or “substantially” preceding a parameter means being within +/−10 percent of that parameter. Modifications are possible in the described examples, and other examples are possible within the scope of the claims.

What is claimed is:

1. A packaged integrated circuit (IC), comprising:
a package substrate having opposite first and second surfaces and including metal interconnects surrounded by an insulation material, the package substrate including a depression region that extends from the first surface, and the depression region including a material different from the insulation material and the metal interconnects;
a semiconductor die on part of the first surface adjacent to the depression region, the semiconductor die including circuitry coupled to the metal interconnects; and
a mold compound covering the semiconductor die and the depression region.

2. The packaged integrated circuit of claim 1, further comprising first metal pads on the first surface and second metal pads on the second surface, wherein the metal interconnects are electrically coupled between the first and second metal pads, and the semiconductor die is mounted on the first metal pads.

3. The packaged IC of claim 2, wherein the depression region is a cavity abutted by the insulation material on at least two sides.

4. The packaged IC of claim 3, wherein the material includes an epoxy polymer.

5. The packaged IC of claim 4, wherein:
the semiconductor die is a first semiconductor die;
the packaged IC further comprises a second semiconductor die on the first surface;
the first semiconductor die is on a first side of the cavity;
the second semiconductor die is on a second side of the cavity opposite to the first side; and
the epoxy polymer is configured as an optoisolator between the first and second semiconductor dies.

6. The packaged IC of claim 1, wherein the mold compound is a first mold compound; and wherein the material includes a second mold compound different from the first mold compound.

7. The packaged IC of claim 6, wherein the second mold compound includes a resin and metal particles, in which the metal particles are suspended in the resin.

8. The packaged IC of claim 7, wherein:
the depression region is a first cavity abutted by the insulation material on at least two sides;
the package substrate further includes a second cavity and a third cavity each extending from the first surface;
the first cavity is between the second and third cavities; and
at least part of the second cavity and the third cavity filled with the second mold compound.

9. The packaged IC of claim 8, wherein the metal interconnects include a coil that surrounds the first cavity, a first portion of the coil extends between the first and second cavities, and a second portion of the coil extends between the first and third cavities.

10. The packaged IC of claim 8, wherein:
the semiconductor die is a first semiconductor die;
the packaged IC further comprises a second semiconductor die on the first surface;
the first semiconductor die is on a first side of the second cavity; and
the second semiconductor die is on a second side of the third cavity opposite to the first side.

11. The packaged IC of claim 1, wherein the depression region includes an indent that abuts the insulation material on one side, and the material is the mold compound.

12. The packaged IC of claim 1, wherein the metal interconnects include a first metal, and the material includes a second metal different from the first metal.

13. The packaged IC of claim 1, wherein:
the package substrate include multiple substrate layers;
each substrate layer includes a metal layer surrounded by the insulation material, the metal layer including at least one of a trace or a via;
the metal layers of adjacent substrate layers in contact with each other to form the metal interconnects; and
the packaged IC includes a first number of substrate layers below the depression region, and a second number of substrate layers abutting the depression region, the second number being higher than the first number.

14. The packaged IC of claim 1, wherein the mold compound is a first mold compound, and the insulation material includes at least one of: a build-up film or a second mold compound.

15. A method, comprising:
forming a first substrate layer, in which the first substrate layer has opposite first and second surfaces and includes: a metal layer extending between the first and second surfaces; and an insulation material abutting the metal layer;
forming a first resist layer on the first surface covering the metal layer;
forming a second substrate layer on the first resist layer, the second substrate layer including the insulation material;
forming a second resist layer on the second surface covering part of the first substrate layer abutting the metal layer;
etching away the metal layer to form a depression region including the first resist layer; and
removing the second resist layer.

16. The method of claim 15, wherein the metal layer is abutted by the insulation material on at least two sides, and the depression region is a cavity; and
wherein the method further comprises filling at least part of the cavity with a second material different from the insulation material.

17. The method of claim 16, wherein the second material includes at least one of: an epoxy polymer or a magnetic mold compound.

18. The method of claim 17, wherein the magnetic mold compound fills the depression region.

19. The method of claim 15, further comprising:
mounting a semiconductor die on part of the second surface abutting the depression region; and
depositing a mold compound over the semiconductor die and depression region.

20. The method of claim 15, wherein the insulation material includes at least one of: a build-up film, or a mold compound.
